(19) United States
(12) Patent Application Publication
(10) Pub. No.: US 2010/0104876 A1
(43) Pub. Date: Apr. 29, 2010

(54) PIEZOELECTRIC COMPOSITE MATERIAL

(75) Inventors: Dou Zhang, Birmingham (GB); Carl Meggs, Birmingham (GB); Timothy William Button, Birmingham (GB); Geoffrey Dolman, Birmingham (GB)

Correspondence Address: SENNIGER POWERS LLP, 100 NORTH BROADWAY, 17TH FLOOR, ST LOUIS, MO, 63102, US

(73) Assignee: THE UNIVERSITY OF BIRMINGHAM, Birmingham (GB)

(21) Appl. No.: 12/529,686

(22) PCT Filed: Mar. 5, 2007
(86) PCT No.: PCT/GB07/00755

§ 371 Date: Dec. 18, 2009

(51) Int. Cl. H01L 41/22; B32B 38/04; B32B 38/08; B32B 37/06; B32B 9/00

(52) U.S. Cl. 428/411.1; 156/250; 156/222; 156/89.12

(57) ABSTRACT

The present invention provides a method for producing a composite material comprising an array of piezoelectric fibres, the method comprising: (a) providing: (a1) a plurality of first strips comprising a piezoelectric material or a precursor to a piezoelectric material, and a first carrier, and (a2) a plurality of second strips comprising a decomposable material, and a second carrier; (b) placing said pluralities of said first and second strips alternately on top of one another to form a stack in which at least a portion of said first strips is separated from adjacent first strips by a second strip; (c) a heating step comprising heating said stack to remove said first and second carriers and said decomposable material; (d) impregnating said stack with a filler material to form a composite stack of piezoelectric strips; and (e) cutting said stack to form a composite material comprising an array of piezoelectric fibres. In an alternative method the cutting (e) is performed before the heating step (c). The methods allow for the production of fibre arrays with mean fibre spacing of 5 ym or less.

The present invention relates to a piezoelectric composite material. More particularly, the present invention relates to a method for forming a composite material comprising an array of piezoelectric fibres and a composite material comprising an array of piezoelectric fibres formed by the method of the present invention.

A composite material comprising an array of piezoelectric fibres typically comprises a monolayer of uniaxially aligned piezoelectric fibres embedded in a polymer matrix. Every fibre is separated by a similar distance from an adjacent and substantially parallel fibre, and it is held in place by the polymer matrix.

Typically, a composite material comprising an array of piezoelectric fibres (such as that provided by the present invention) may be used as, for example, an actuator and/or a sensor. Devices with combined sensing and actuating functions are more usually called transducers, and such devices have wide application in, for example, vibration control and energy harvesting.

In order to be used in these applications, electrodes are deposited around the composite material. Although several types of electrode design have been proposed, the use of one type of electrode, called an interdigited electrode (IDE), is considered as advantageous. This type of electrode is deposited on top of and underneath the composite material, across the array of fibres. This takes advantage of the longitudinal ‘d33’ piezoelectric effect, which results in nearly twice the strain actuation than with the weaker ‘d31’ piezoelectric effect used in conventional through-plane poled piezoelectric actuators.

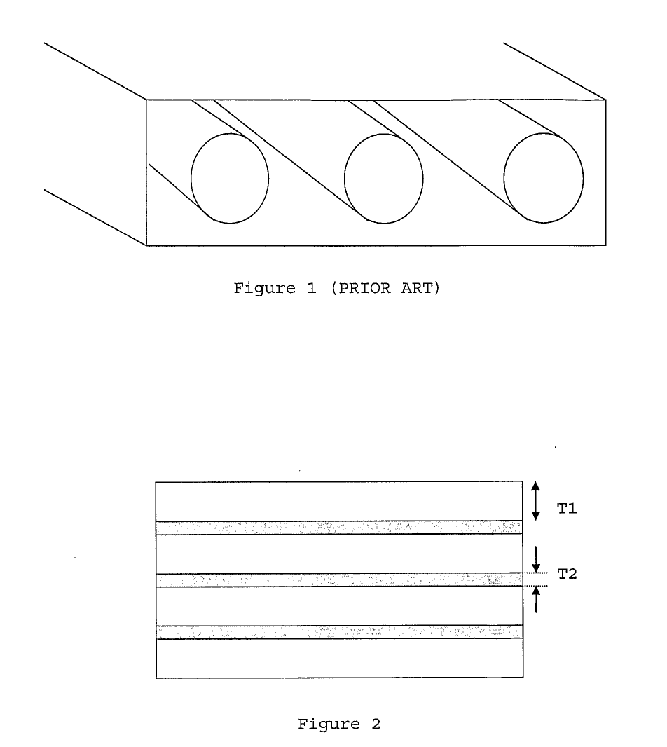

An example of a typical piezoelectric fibre composite in which circular fibres are embedded in a polymer matrix is shown in FIG. 1. In this Figure, individual fibres of piezoelectric material may be manufactured by extrusion. The individual fibres are then embedded in a polymer matrix. This type of piezoelectric fibre composite is described in, for example, U.S. Pat. No. 6,048,622.

The inventors have recognised that the use of a composite material comprising an array of piezoelectric fibres is beneficial, particularly when used in combination with interdigited electrodes. However, the inventors have recognised that the composition of conventional composite materials comprising arrays of piezoelectric fibres can be improved. Therefore, the inventors have designed and manufactured a new type of composite material comprising an array of piezoelectric fibres.

Accordingly, the present invention provides a method for producing a composite material comprising an array of piezoelectric fibres, the method comprising:
(a) providing:
   (a1) a plurality of first strips comprising a piezoelectric material or a precursor to a piezoelectric material, and a first carrier, and
   (a2) a plurality of second strips comprising a decomposable material, and a second carrier;
(b) placing said pluralities of said first and second strips alternately on top of one another to form a stack in which at least a portion of said first strips is separated from adjacent first strips by a second strip;
(c) a heating step or steps comprising heating said stack to remove said first and second carriers and said decomposable material;
(d) impregnating said stack with a filler material to form a composite stack of piezoelectric strips; and
(e) cutting said stack to form a composite material comprising an array of piezoelectric fibres.

The present invention also provides a method for producing a composite material comprising an array of piezoelectric fibres, the method comprising:
(a) providing:
   (a1) a plurality of first strips comprising a piezoelectric material or a precursor to a piezoelectric material, and a first carrier, and
   (a2) a plurality of second strips comprising a decomposable material, and a second carrier;
(b) placing said pluralities of said first and second strips alternately on top of one another to form a stack in which at least a portion of said first strips is separated from adjacent first strips by a second strip;
(c) cutting said stack to form an array of piezoelectric fibres;
(d) a heating step or steps comprising heating said array to remove said first and second carriers and said decomposable material; and
(e) impregnating said stack with a filler material to form a composite material comprising an array of piezoelectric fibres.

Preferably, for both the above embodiments, the first and/or second carriers comprise a binder material and a solvent. Preferably, the first and/or second strips are formed by a viscous plastic process. Preferably, the stack is calendered in between steps (b) and (c). Preferably, the (minimum) mean thickness of the second strips in the stack is less than 5 μm. Preferably, the piezoelectric material comprises doped and/or un-doped lead zirconate titanate. Preferably, the piezoelectric material and the piezoelectric material precursor are provided in a total amount of 70 to 95 wt. % of the first strip. Preferably, the decomposable material comprises elemental carbon. Preferably, the decomposable material is provided in an amount of 30 to 60 wt % of the second strip. Preferably, in the heating step:
(i) the stack is heated at a temperature and time sufficient to remove said first and second solvents;
(ii) then the stack is heated at temperatures and times sufficient to remove the first and second binders and the decomposable material; and then
(iii) the stack is heated at a temperature and time sufficient to sinter the piezoelectric material.

Preferably, the first and/or second solvents comprise cyclohexanone and/or water, and in this case, the stack is heated at a temperature of 30 to 100° C. Preferably, the first and/or second binders comprise polyvinyl butyral and/or polyvinyl alcohol, and in this case, the stack is heated in step (c2) to remove the decomposable material at a temperature of between 650 to 800° C. Preferably, the stack is heated in step (c2) to remove the first and second binders at a temperature of between 250 and 800° C. Preferably, the filler material comprises an epoxy resin. Preferably, the method further comprises depositing one or more electrodes on the composite material, the electrodes being configured to be capable of producing an electric field across at least part of the array of piezoelectric fibres.

The present invention also provides an array of piezoelectric fibres, wherein individual piezoelectric fibres are orientated substantially parallel to one another and the mean minimum separation between two adjacent fibres is 5 μm or less. Preferably, the individual piezoelectric fibres have a substantially quadrilateral cross-section. Preferably, the array is manufactured by the method describe above. Preferably, this array is used in an actuator, sensor or transducer.

The present invention also provides a stack comprising alternate strips of:
(i) a piezoelectric material or a precursor to a piezoelectric material, and a first carrier, and
(ii) a decomposable material, and a second carrier.

As used herein, an ‘array’ refers to an ordered arrangement of fibres. In at least a portion of the array, each individual fibre does not touch or join onto another fibre.

As used herein, a ‘carrier’ is a substance in which the piezoelectric material or decomposable material is contained to form a plastically formable material. It may comprise, for example, a binder and a solvent, and/or a thermoplastic system. Preferably, it should be removed leaving behind the (e.g.) piezoelectric material when heated (e.g. at 800° C. or below). Preferably, if the material contained in the carrier is in particulate form, the carrier is capable of holding the material in a pseudo-stable non-agglomerated form. As such, the carrier may be of doughy consistency.

The ‘binder’ is preferably a material that forms a carrier when mixed with a solvent.

As used herein, a ‘strip’ refers to an approximately cuboid shape. Its greatest dimension is its length, the middle dimension is its width and its smallest dimension is its thickness. A strip preferably retains its shape and therefore does not significantly deform without external influence or force. However, when an external force is applied to the strip, the strip is preferably capable of deforming. As such, a strip is preferably formed from a doughy material.

As used herein, a ‘filler material’ is any material suitable for impregnating the array of the present invention. It may be, for example, a thermosetting resin, for example an epoxy resin. This has the advantage that the liquid resin may be impregnated into the array in its malleable (e.g. liquid) form; then, the resin may be hardened after impregnation. In certain cases, a thermoplastic material may also be used.

The method of the present invention typically provides individual piezoelectric fibres that are substantially quadrilateral in shape. The fibres may be, for example, substantially rectangular in shape, depending on exactly how the stack is cut. This may be advantageous over prior art methods that use circular fibres because, when electrodes are deposited onto the array, the quadrilateral shape allows for better contact between the piezoelectric fibres and the electrodes. This leads to an increase in both the magnitude and uniformity of the electric field across the fibre, and increased stiffness, energy density and strain.

In order to illustrate the advantages of the method of the present invention and the arrays produced by the method of the present invention over conventional methods and arrays, and to exemplify particular embodiments of the present invention, individual aspects of the present invention are described in greater detail below. Although particular embodiments are described individually in relation to each particular method step, each embodiment is intended to be used in combination with any other embodiment unless otherwise stated.

### The First Strip

The first strip comprises a piezoelectric material or a precursor to a piezoelectric material and a first carrier.

The piezoelectric material may be lead zirconate titanate (PZT). This is a ceramic perovskite material with the general structure Pb[ZrₓTi₁₋ₓ]O₃, where 0<x<1. It may be provided in any form known to the person skilled in the art. As such, it may be provided in its ‘hard’ or ‘soft’ form. It may be provided either doped or un-doped. If it is doped, it may be doped with, for example, La, Nd, Sb, Ta, Nb and W (which result in soft PZT); Fe, Co, Mn, Mg, Al, In, Cr, Sc, Na and K (which are acceptor dopants that result in hard PZT); isovalent substitutions including Sr, Ca, Ba and Sn; and multivalent additives such as Cr, U and Mn.

Other piezoelectric materials that can be used in conjunction with the present invention include other lead based piezoelectric ceramics such as BaTiO₂, PbTiO₂, PbNb₂O₆, Pb(Mg_{1/3}Nb_{2/3})O₃, and lead-free piezoelectric ceramic such as alkaline niobates (KNbO₂, KNaNb₂O₆, LiNbO₂) and modified bismuth titanates (SrBi₂Ti₂O₉, NaBiTi₄O₁₀). Precursors to piezoelectric materials may also be used. For example, oxides of lead, titanium and zirconium may be mixed in proportions so that piezoelectric lead zirconate titanate is formed after appropriate heating.

The first strip is made by mixing the piezoelectric material with the first carrier. As such, the piezoelectric material is usually provided in powder form. The size of the particles in the powder may be 0.05 to 10 μm, more preferably 0.1 to 5 μm, and more preferably in the range of 0.5 μm to 1 μm. These values are the d50 value. The inventors have found that this distribution of particle sizes is beneficial because it optimises the packing of the solid (solids loading) and the viscosity of the mixture resulting in the improvement in the homogeneity, density and electric properties of the composite.

The piezoelectric material is preferably provided in an amount of 70 wt % or greater as a proportion of the total composition of the first strip (i.e. every 100 g strip material contains 70 g or more of piezoelectric material). If it provided below this amount, the density of piezoelectric material in the final array is too low for some applications. More preferably, the piezoelectric material is provided in an amount of 80 wt % or greater.

The piezoelectric material is preferably provided in an amount of 95 wt % or less as a proportion of the total composition of the first strip. If it is provided in above this amount, the workability of the first strip tends to be reduced, making it more difficult to handle the composition in the subsequent processing steps. This is because the composition of the first strip becomes crumbly and less fluid-like. More preferably, the piezoelectric material is provided in an amount of 90 wt % or less.

The first carrier, which is mixed with the piezoelectric material, may comprise a binder material and a solvent. The binder material preferably produces a viscous solution when mixed with the solvent in appropriate concentration. Typically, the binder and the solvent are mixed in a ratio of their weights of 1:5 to 5:1, more preferably 1:3 to 3:1. This usually results in a carrier with suitable viscosity. If too much binder is added, the solution becomes too viscous and the workability of the resulting material is too low. Whereas if too little binder is added, the solution becomes too fluid and the cohesiveness and workability of the resulting material is reduced.

Preferably, the binder material comprises one or more of polyvinyl alcohol (PVA), methylcellulose, hydroxypropyl methylcellulose, and polyvinyl butyral (PVB). These binder materials are preferred because they provide clean burn-out. In addition, they are commercially readily-available and safe.

The solvent may be any solvent that dissolves or suspends the binder material. The solvent may be aqueous and/or organic. PVA, methylcellulose and hydroxypropyl methylcellulose may be used in an aqueous system (with water as the solvent). PVB may be used with cyclohexanone and/or tert-butyl alcohol as the solvent.

The first carrier system can also comprise an epoxy-group containing substance and/or a precursor that is capable of reaction (e.g. polymerisation) when exposed to UV radiation, for example methyl methacrylate.

Other components may also be added to the mixture of the carrier and piezoelectric powder. For example, a dispersant may be added to help to prevent the agglomeration of the piezoelectric particles in the carrier. Examples of dispersants are stearic acid (preferably used in combination with a PVB binder) and ammonium polyacrylate (preferably used in combination with a PVA binder). To be effective in its role as a dispersant, the dispersant may be provided as an amount of 0.01 to 1 wt % of the composition of the first strip. Plasticers may also be added to the composition to improve the workability of the composition used to form the first strip. An example of such a plasticer is di-n-butyl phthalate. To be effective in its role as a plasticer, the plasticer may be provided in an amount of 0.1 to 5 wt % of the composition of the first strip.

All the components of the first strip may be mixed together using any conventional mixing process. However, all the components of the first strip are preferably mixed together using a viscous plastic process In this process, the components are mixed under high shear conditions, for example by using a twin-roll milling technique. The viscous plastic process is discussed in general in the following documents:
1) BR8505794 (Composition comprising ceramic particles);
2) BR8801931 (Article of ceramic material and production thereof); and
3) High-strength ceramics through colloidal control to remove defects, Nature 1987, 330, 51-53.

The advantage of the viscous plastic process over, for example, simply mixing the components together under normal conditions and producing a conventional tape is that it helps to prevent the agglomeration of individual particles and promote the homogeneity of the macrostructures of the paste system. This leads to a higher density in both green and sintered states and a more uniform final array which has more uniform properties. This is beneficial over structures formed from conventional tapes, especially in the large-scale production of the arrays.

After the mixing process (whatever its nature) a composition with a doughy or pasty consistency is produced. The dough or paste is preferably essentially plastic in its properties, so that it deforms and changes its shape when subjected to an externally applied stress, but retains its new shape when the stress is removed. The dough can be extruded through a die piece to form a strip (or tape).

The thickness of the strip after extrusion is typically 500 to 1000 μm. Therefore, in order to create finer features in the final array, the strip can be calendered. This is carried out in a conventional manner at ambient temperature (e.g. 15 to 50° C.) by passing the strip through a pair of counter-rotating rollers, where the gap between the rollers and the pressure applied between them can be adjusted. In order to produce an even thickness of the calendered strip and in order to prevent the strip from sticking to the rollers of the calender apparatus, polyethylene sheets may be placed on the top and bottom surfaces of the strip. The polyethylene sheets typically have a thickness of 50 to 200 μm, although any conventional polyethylene sheet may be used.

Each calendering process typically reduced the thickness of the strip by half. After several cycles of calendering, the thickness of the tape is typically reduced to 20 and 200 μm.

### The Second Strip

The second strip comprises a decomposable material and a second carrier material.

The decomposable material in the second strip may also be called a ‘fugitive’ material. It is decomposable on heating. It will typically decompose at a temperature of less than 800° C., more preferably less than 700° C., for example less than 600° C. The presence of oxygen gas may be required in some cases for the decomposition, for example at a partial pressure of 0.005 atmospheres or greater, more preferably at a partial pressure of 0.05 atmospheres or greater. In other cases, the decomposition may be carried out in the absence of oxygen.

For example, carbon may be used as the decomposable material. Carbon will decompose into gaseous products when heated in an oxygen atmosphere to typically 650° C. or above.

Other materials that may be used as the decomposable material are organic materials such as starch.

Ideally, the decomposable material is provided in as great a quantity as possible in the second strip (e.g. 30 wt % or greater as a proportion of the total composition of the second strip, more preferably 35 wt %). This facilitates the clean ‘burn-off’ of the second strip in the subsequent burn-out steps. However, the decomposable material is in practice preferably provided in an amount of 60 wt % or less as a proportion of the total composition of the second strip. If it is provided in above this amount, the workability of the second strip tends to be reduced, making it more difficult to handle the composition in the subsequent processing steps. This is because the composition of the second strip becomes crumbly and less fluid-like. More preferably, the decomposable material is provided in an amount of 50 wt % or less.

The other properties and processing features of the second strip are the same as for the first strip and for the same reasons. In particular, the viscous plastic process used to make the strip is carried out under the same preferred conditions as for the first strip.

This type of fugitive layer is advantageous over conventional methods of providing fugitive layers. For example, U.S. Pat. No. 6,183,578 prints a fugitive ink onto a conventional piezoelectric tape. In contrast, by providing the fugitive layer in the form of a strip made by, for example, viscous plastic processing, the present invention allows for the precise control of the dimensions of final array of piezoelectric fibres. Furthermore, the fugitive layer of the present invention allows for the calendering of the stack of strips (see below), which can result in piezoelectric fibres with small and controlled separations between adjacent fibres.

### The Stack of Strips

Once the first and second strips have been formed, they are placed alternately on top of one another to form a stack. Although it is possible to alter this arrangement (e.g. by placing two first strips next to one another), it is preferred that at least a proportion of the first strips is separated from adjacent first strips by at least one second strip. This arrangement is shown in FIG. 2. In this Figure, the first strips are shown in white and the second strips are shown in grey. The thickness of the two layers is illustrated as T1 and T2. It should be noted that, if the two surfaces of a layer are not parallel, then the thickness of the layer at any particular point along one surface is defined as the minimum thickness of the layer. To obtain the overall average (mean) thickness of the layer, the thickness of the layer is averaged over the length of the layer.

Typically, 50 to 500 first and second strips in total are stacked on top of one another. Typically, the stack will be 1 to 4 cm thick. The present inventors have found these parameters to be set by the constraints of the lamination process.

The stack of strips are laminated together using conventional means. For example, a commercial laminator, such as a OMNICROM CT1000 (supplied by Times Graphic Centres) can be used.

Once the laminated stack of strips has been formed, it may be further calendered to decrease the thickness of the layers. This is carried out in the same manner as the calendering of the individual strips. After this calendering, the thickness of the second strips may be decreased to below 5 μm, for example 2 μm or below, and sometimes as low as 0.5 μm. This technique therefore allows for an array having a small separation between adjacent fibres to be produced. The thickness of the second strips may be less than 100 μm, for example less than 50 μm, and sometimes as low as 5 μm.

The thickness of the laminated stack of strips can be increased by pressing two or more stacks together with a conventional pressing tool. The inventors have found that the pressing conditions of 25-120° C., 10-100 MPa initial pressure and 10-120 min holding time are preferred.

### Heating, Impregnating and Cutting

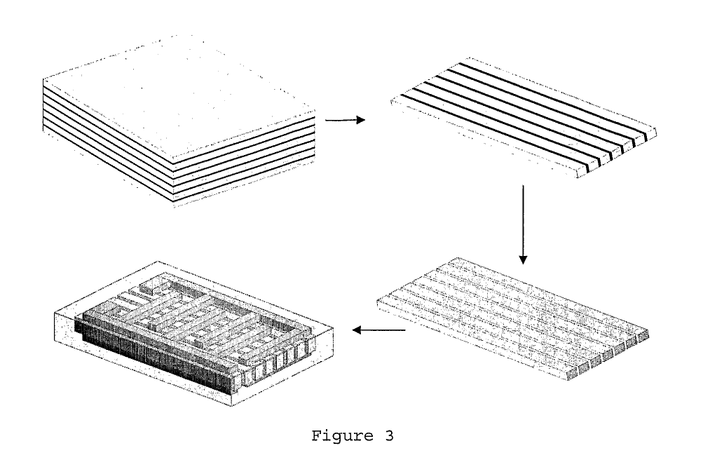

After formation and lamination of the stack, the stack is heated, impregnated with a filler material and cut. One embodiment of this process is illustrated in FIG. 3. This figure illustrates how the stack may be cut before heating. The present inventors have found that this has the advantage that the burn-out of the fugitive layer occurs quickly in this embodiment due to the high surface area present in the burn-out step. This can lead to decreased heating and sintering times.

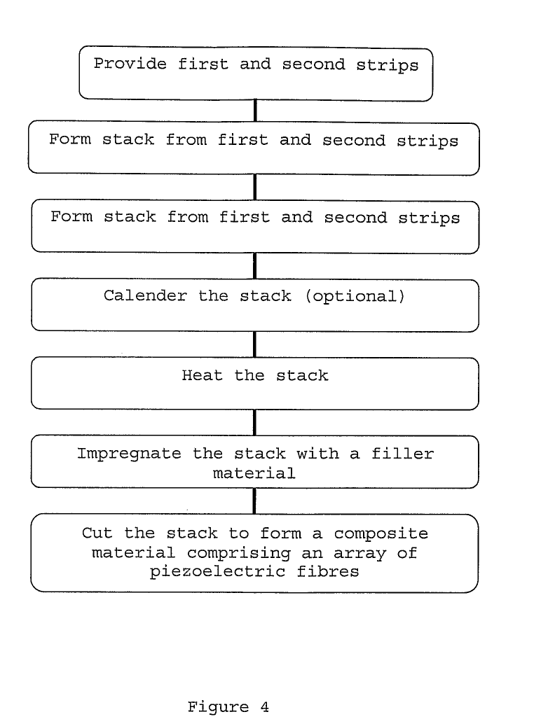

An alternative embodiment is illustrated by the flow-chart in FIG. 4. In this embodiment, the stack is heated, impregnated with a filler resin and then cut. This embodiment has two advantages over cutting the stack prior to heating. Firstly, the properties of the filler material can be selected so as to provide good mechanical properties, thereby facilitating the cutting of the body and helping to ensure that the cutting process is clean and even. In addition, it allows for the more efficient heating and sintering of the stack because many arrays of piezoelectric fibres can be produced by one cycle of heating. In contrast, if the stack is cut into individual arrays before heating, each array needs to be individually sintered. Therefore, the alternative embodiment is advantageous, especially for the large-scale production of arrays of piezoelectric fibres.

This alternative embodiment is especially preferred for stacks 4 cm or less thick, in which the present inventors have found that the gaseous products produced by the decomposition of the decomposable product and the carrier materials can escape sufficiently fast and efficiently under the heating conditions.

Suitable filler materials include epoxy resins. An example of a suitable epoxy resin CY1301/HY1300 (Vantico Polymer Specialties Division, Switzerland), with CY 1301 as the base resin and HY1300 as the hardener.

Generally, the heating step comprises three separate stages:
(i) the stack (cut or uncut) is heated at a temperature and time sufficient to remove the first and second solvents;
(ii) then the stack is heated at temperatures and times sufficient to remove the first and second binders and the decomposable material; and then
(iii) the stack is heated at a temperature and time sufficient to sinter the piezoelectric material.

The three step heating process described above allows for the efficient and effective removal of the decomposable material and the binders (i.e. the carriers) before sintering. An oxygen atmosphere may promote the removal of some of the components.

For the heating process, the stack may be hung in a furnace using platinum wire. The platinum wire is woven through small holes bored through the stack material. This method of heating allows for even stress distribution throughout the stack during heating. This also avoids getting contaminant into the layered structures during heating.

The first step of this heating process is the removal of the solvent. Solvents used in the present invention are usually relatively volatile and therefore the stack need only be heated at a temperature of 30 to 100° C. (for example at around atmospheric pressure) to remove the solvent. The exact drying process will depend on the size, thickness and number of layers in the stack. For example, a stack of 4 cm thickness or more may require 2 or more days to sufficiently dry out. Whereas a thinner stack of 0.5 cm or less may require less than 2 days to sufficiently dry out. If the stack has been cut prior to heating, a heating time of 6 hours or more may only be required. The heating may be carried out under vacuum to facilitate the removal of the solvent (e.g. at 0.1 atmospheres pressure or less, more preferably 0.01 atm pressure or less). It can also be carried out in an inert atmosphere.

The second step of this heating process is the removal of the binders and the decomposition of the decomposable material. The decomposable material, such as carbon, will typically decompose at a temperature of 650 to 800° C. Again, the exact process will depend on the size, thickness and number of layers in the stack. For example, a stack of 4 cm thickness or more may require over 24 hours for the complete decomposition of the decomposable material. Whereas a thinner stack of 0.5 cm or less may require less than 24 hours for the decomposable material to decompose. If the stack has been cut prior to heating, a heating time of 12 hours or less may only be required. As the decomposable material often requires oxygen to be present in order for the material to decompose, this step is often carried out in an oxygen-containing atmosphere (e.g. at 0.005 atm or more partial pressure of oxygen, more preferably at 0.05 atm or more partial pressure of oxygen), for example in air.

Binders, such as polymers based on a polyethylene or polyvinylene backbone, will typically be removed at a temperature of 250 to 800° C. Again, the exact heating process will depend on the size, thickness and number of layers in the stack. For example, a stack of 4 cm thickness or more may require over 24 hours for the binders to be removed. Whereas a thinner stack of 0.5 cm or less may require less than 24 hours for the binders to be removed. If the stack has been cut prior to heating, a heating time of 12 hours or less may only be required. Depending on the type of binder and fugitive material being used, it may be carried out without the presence of oxygen (e.g. at than 0.005 atm or less partial pressure of oxygen, more preferably in an atmosphere substantially free of oxygen). The heating can also be carried out in an inert atmosphere (e.g. under a noble gas, for example argon).

The third step of this heating process is the sintering of the piezoelectric material. This is typically carried out at a temperature of above 1000° C., for example 1200° C., in an air or oxygen atmosphere. The temperature will usually be less than 1400° C. because adverse reactions may occur in the stack during sintering. The time required for sintering is relatively independent of the stack size, and is typically 20 minutes to 2 hours. The precise conditions (maximum temperature, dwell time and atmosphere) of the sintering step will be dependent on the type of piezoelectric material being used in the composite. Values given here may be used, for example, for the lead zirconate titanate materials. For some materials sintering may be carrier out without the presence of oxygen (e.g. at than 0.005 atm or less partial pressure of oxygen, more preferably in an atmosphere substantially free of oxygen). The heating can also be carried out in an inert atmosphere (e.g. under a noble gas, for example argon).

The exact temperatures suitable for removing the binders, for decomposing the decomposable material and for sintering can be determined by Differential Scan Calorimetry (DSC).

The sintering process may also lead to the densification of the piezoelectric material. This will be understood by the person skilled in the art.

After sintering, the stack (cut or uncut) is allowed to cool, and then, usually under vacuum, the stack is impregnated with the filler material. This is carried out by mixing the resin and the hardener thoroughly. For the particular example of the epoxy resin CY1301/HY1300 mixture, a weight ratio of 100:30 is used. The impregnating of the mixture to the stack is carried out in a vacuum condition, (i.e. preferably 0.1 atmospheres pressure or less, more preferably 0.01 atmospheres or less).

As explained above, the stack can be cut either before or after heating. In either case, the stack is cut with [a precision cutting tool, for example, Accutom-50 (Struers).

Optionally, the strip of the composite material may be lapped to further reduce and/or control the thickness if necessary.

### Adding Electrodes

Finally, once the composite material comprising an array of piezoelectric fibres has been formed, electrodes can be added to the array. Preferably, these are interdigital electrodes.

To make the interdigited electrodes, the electrode pattern is usually printed onto a polymer film. The inventors have found that the screen printing technique can be used to produce the required IDE pattern (e.g., silver epoxy) on a polyimide film. In particular, the inventors found that printed circuit board (PCB) technique is preferred to produce the interdigital electrodes (e.g., Cu) on the polyimide film with better surface quality and conductivity.

The skilled person will appreciate that many other materials, such as Au, can be used as electrode materials.

### Products

The present invention also relates to certain products produced by the method of the present invention. In particular, the present invention relates to products made by the method of the present invention. These include the laminated stack of first and second strips. The preferred features of these first and second strips are described above.

The present invention also relates to an array of piezoelectric fibres, wherein individual piezoelectric fibres are orientated substantially parallel to one another and the mean minimum separation between two adjacent fibres is 5 μm or less. Preferably, the individual piezoelectric fibres have a substantially quadrilateral cross-section. This array can be manufactured by the method of the present invention.

The present invention also relates to an actuator comprising the array of the present invention. This actuator may be used in, for example, adaptable mirrors and lenses, and vibration and noise control and energy harvesting.

### EXAMPLES

A piezoelectric dough was made from the following composition by viscous plastic processing: 1000 g PZT, 55 g PVB, 45 g Cyclohexanone, 25 g Di-n-butyl phtalate, and 1 g stearic acid.

A fugitive dough was made from the following composition by viscous plastic processing: 300 g Carbon, 100 g PVB, 130 g Cyclohexanone, 60 g Di-n-butyl phtalate, and 1 g stearic acid.

The VPP compositions were then individually put into a barrel and pushed through a die piece to form strips. The strips were then placed inside separate polyethylene bags and calendered (separately) until the required thickness were obtained. The polythene bag was changed after each calendering. The polythene had a thickness of 0.11 mm.

It is contemplated that the two compositions could also be coextruded to produce a laminar structure.

The formation of PZT and carbon stack was carried out by lamination and calendering. The building of the multi-layer was achieved by joining two fresh layers of PZT and Carbon (after peeling off the polythene) with top and bottom sides protected by polythene. The lamination was carried out using a commercial laminator (OMNICROM CT1000 (Times Graphic Centres)), with the temperature set to 1.5. The laminate was then pressed. In this case, the laminate was pressed at 80° C. and 50 to 60 MPa for 60 minutes.

The laminated stack was then dried. The drying process was found to be dependent on the size, the thickness, and the numbers of the layers of the laminate. For a thin stack of 0.5 cm thickness or less, it took about 24 hours in 40 and 80° C., respectively. For a green laminate as a whole with a thickness of 4 cm, it took 3 to 4 days at 80° C. Drilling several holes in the bulk parts (parts of pure PZT) of the laminate, which was also used for the platinum wires for hanging purpose in the later sintering process, was found to help the release of the drying stress. For the thicker green body, a small amount of load was placed on the body to help maintain its shape.

The green laminate was then sintered. Holes were drilled in the laminate of around 1 to 2 mm diameter. Platinum wire was used to hang the laminate from an alumina bar in the furnace. The following heating/sintering profiles were carried out:
(i) For the thick laminate: 1° C./min to 325° C. for 12 hours; 1° C./min to 600° C. for 15 hours; 5° C./min to 1200° C. for 2 hours; 5° C./min to 40° C.
(ii) For the thin slice: 1° C./min to 325° C. for 4 hours; 1° C./min to 600° C. for 8 hours; 5° C./min to 1200° C. for 1 hours; 5° C./min to 40° C.

The laminate was then back-filled with epoxy, cut and IDE electrodes were assembled on both surfaces.

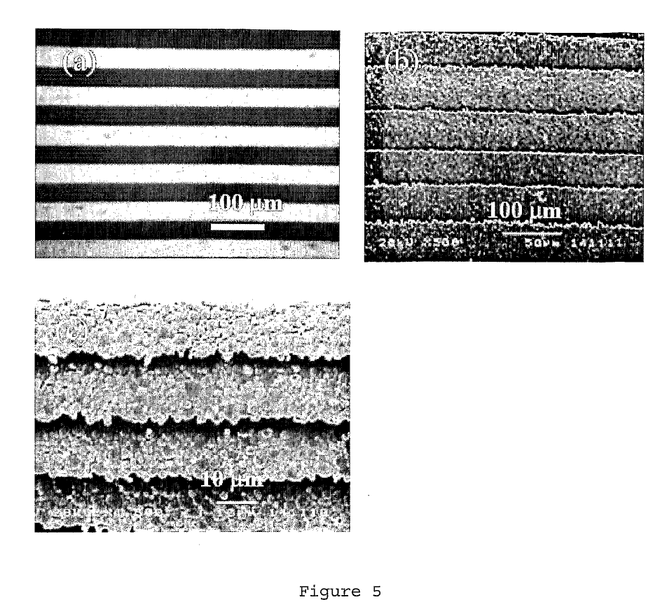

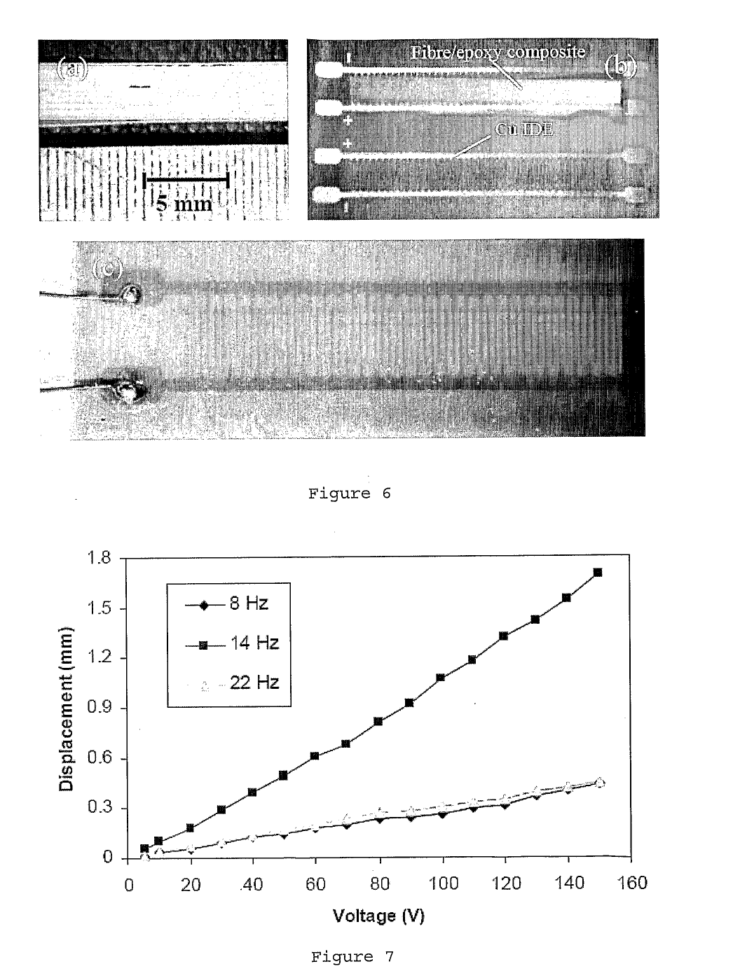

An example of a stack (green body) formed as an intermediate prior to sintering is shown in FIG. 5A. Examples of composites made using this method are shown in FIGS. 5B to C. An example of a composite connected up to a set of electrodes is shown in FIGS. 6A to C. The displacement results from this composite (attached to a 0.25 mm sheet of copper) are shown in FIG. 7.

1. A method for producing a composite material comprising an array of piezoelectric fibres, the method comprising:
(a) providing:
(a1) a plurality of first strips comprising a piezoelectric material or a precursor to a piezoelectric material, and a first carrier, and
(a2) a plurality of second strips comprising a decomposable material, and a second carrier;
(b) placing said pluralities of said first and second strips alternately on top of one another to form a stack in which at least a portion of said first strips is separated from adjacent first strips by a second strip;
(c) a heating step or steps comprising heating said stack to remove said first and second carriers and said decomposable material;
(d) impregnating said stack with a filler material to form a composite stack of piezoelectric strips; and
(e) cutting said stack to form a composite material comprising an array of piezoelectric fibres.

2. A method for producing a composite material comprising an array of piezoelectric fibres, the method comprising:
(a) providing:
(a1) a plurality of first strips comprising a piezoelectric material or a precursor to a piezoelectric material, and a first carrier, and
(a2) a plurality of second strips comprising a decomposable material, and a second carrier;
(b) placing said pluralities of said first and second strips alternately on top of one another to form a stack in which at least a portion of said first strips is separated from adjacent first strips by a second strip;
(c) cutting said stack to form an array of piezoelectric fibres;
(d) a heating step or steps comprising heating said array to remove said first and second carriers and said decomposable material; and
(e) impregnating said stack with a filler material to form a composite material comprising an array of piezoelectric fibres.

3. The method according to claim 1, wherein the first and/or second carriers comprise a binder material and a solvent.

4. The method according to claim 1, wherein the first and/or second strips are formed by a viscous plastic process.

5. The method according to claim 1, wherein the stack is calendered in between steps (b) and (c).

6. The method according to claim 1, wherein the mean thickness of the second strips in the stack is less than 5 μm.

7. The method according to claim 1, wherein the piezoelectric material comprises doped and/or un-doped lead zirconate titanate.

8. The method according to claim 1, wherein the piezoelectric material and the piezoelectric material precursor are provided in a total amount of 70 to 95 wt % of the first strip.

9. The method according to claim 1, wherein the decomposable material comprises elemental carbon.

10. The method according to claim 1, wherein the decomposable material is provided in an amount of 30 to 60 wt % of the second strip.

11. The method according to claim 3, wherein in the heating step:
(i) the stack is heated at a temperature and time sufficient to remove said first and second solvents;
(ii) then the stack is heated at temperatures and times sufficient to remove the first and second binders and the decomposable material; and then
(iii) the stack is heated at a temperature and time sufficient to sinter the piezoelectric material.

12. The method according to claim 3, wherein the first and/or second solvents comprise cyclohexanone and/or water.

13. The method according to claim 11, wherein the stack is heated at a temperature of 30 to 100° C.

14. The method according to claim 3, wherein the first and/or second binders comprise polyvinyl butyral and/or polyvinyl alcohol.

15. The method according to claim 11, wherein the stack is heated in step (c2) to remove the decomposable material at a temperature of between 650 to 800° C.

16. The method according to claim 9, wherein the stack is heated in step (c2) to remove the first and second binders at a temperature of between 250 and 800° C.

17. The method according to claim 1, wherein the filler material comprises an epoxy resin.

18. The method according to claim 1, wherein the method further comprises depositing one or more electrodes on the composite material, the electrodes being configured to be capable of producing an electric field across at least part of the array of piezoelectric fibres.

19-22. (canceled)

23. A stack comprising alternate strips of:
(i) a piezoelectric material or a precursor to a piezoelectric material, and a first carrier, and
(ii) a decomposable material, and a second carrier.
